(19) United States
(12) Patent Application Publication
(10) Pub. No.: US 2025/0324527 A1
(43) Pub. Date: Oct. 16, 2025

(54) WATERPROOF BRACKET AND ELECTRONIC DEVICE COMPRISING SAME

(71) Applicant: Samsung Electronics Co., Ltd., Suwon-si (KR)

(72) Inventor: Yonghwa KIM, Suwon-si (KR)

(21) Appl. No.: 19/251,128

(22) Filed: Jun. 26, 2025

Related U.S. Application Data
(63) Continuation of application No. PCT/KR2024/000617, filed on Jan. 12, 2024.

(30) Foreign Application Priority Data
Jan. 12, 2023 (KR) 10-2023-0004655
Mar. 28, 2023 (KR) 10-2023-0040407

(51) Int. Cl. H05K 5/06; H05K 5/00

(52) U.S. Cl. CPC H05K 5/069; H05K 5/0017

(57) ABSTRACT

An electronic device is provided. The electronic device including at least one electrical component, a button exposed to an exterior of the electronic device and configured to receive an input from a user, a button cable electrically connected to the button and configured to transmit an input signal from the button, and a waterproof bracket having a first surface positioned in an area exposed to moisture introduced from the exterior of the electronic device and a second surface positioned in an area not exposed to moisture, wherein the waterproof bracket includes a mount configured such that the electrical component is placed therein, and a cable hole provided through the waterproof bracket from the first surface to the second surface, and wherein the button cable extends through the cable hole towards a position of the second surface.

### CROSS-REFERENCE TO RELATED APPLICATION(S)

This application is a continuation application, claiming priority under 35 U.S.C. § 365 (c), of an International application No. PCT/KR2024/000617, filed on Jan. 12, 2024, which is based on and claims the benefit of a Korean patent application number 10-2023-0004655, filed on Jan. 12, 2023, in the Korean Intellectual Property Office, and of a Korean application number 10-2023-0040407, filed on Mar. 28, 2023, in the Korean Intellectual Property Office, the disclosure of each of which is incorporated by reference herein in its entirety.

### BACKGROUND

### 1. Field

The disclosure relates to an electronic device providing a waterproof function. More particularly, the disclosure relates to a waterproof bracket and an electronic device including the same.

### 2. Description of Related Art

An electronic device may be exposed to moisture from the exterior when used in various environments. Moisture may cause malfunctions or failures, such as short circuits, transmission errors, and corrosion of the internal circuits of the electronic device. Accordingly, various waterproofing means have been applied to electronic devices.

An electronic device may include physical buttons for controlling various operations. For example, the electronic device may include buttons for operating certain functions, such as a volume adjustment button, a power button, and/or an AI assistant. In various embodiments, the physical buttons may incorporate various biometric signal sensors, such as a fingerprint sensor. Since the above-mentioned physical buttons are likely to allow moisture to enter from the exterior, various waterproofing means may be applied to address this issue.

The above information is presented as background information only to assist with an understanding of the disclosure. No determination has been made, and no assertion is made, as to whether any of the above might be applicable as prior art with regard to the disclosure.

### SUMMARY

To mount the above-mentioned buttons, an electronic device may have a button mounting space provided therein. The buttons may be inserted into the electronic device from the interior through the space and assembled to be exposed to the exterior through button holes provided in a side surface of the housing of the electronic device. In this case, since the space remains empty after the assembly of the button device is completed, a waterproof bracket may be disposed in the space to prevent liquid (e.g., water) introduced from the exterior of the electronic device through the button hole from entering the interior of the electronic device. However, since the waterproof bracket has no functions other than supporting the buttons and providing a waterproof function, the waterproof may generate dead space.

Aspects of the disclosure are to address at least the above-mentioned problems and/or disadvantages and to provide at least the advantages described below. Accordingly, an aspect of the disclosure is to provide a structure configured to reduce dead space in a housing caused by assembling a button device to the housing while maintaining the waterproofness of the housing. For example, dead space generated in the housing is reduced by minimizing the space used for assembling the button device.

Additional aspects will be set forth in part in the description which follows and, in part, will be apparent from the description, or may be learned by practice of the presented embodiments.

In accordance with an aspect of the disclosure, an electronic device is provided. The electronic device includes at least one electrical component, a button exposed to an exterior of the electronic device and configured to receive an input from a user, a button cable electrically connected to the button and configured to transmit an input signal of the button, and a waterproof bracket having a first surface positioned in an area exposed to moisture introduced from the exterior of the electronic device and a second surface positioned in an area not exposed to moisture, wherein the waterproof bracket includes a mount configured such that the electrical component is placed therein, and a cable hole provided through the waterproof bracket from the first surface to the second surface, and wherein the button cable extends through the cable hole toward a position of the second surface.

In various embodiments, the waterproof bracket includes a cable sealing member configured to seal the cable hole.

In various embodiments, the waterproof bracket includes a seal positioned at a boundary between the first surface and the second surface.

In various embodiments, the mount includes a recess having an opening on the second surface and configured to accommodate the electrical component.

In various embodiments, the electrical component includes a cable extending from the recess to the interior of the electronic device through the opening.

In various embodiments, the electrical component includes a directional antenna, and the directional antenna may be configured to radiate a signal toward the opening.

In various embodiments, at least a portion of an area of the mount in contact with the electrical component is made of a metal material.

In various embodiments, the electronic device includes a first thermal interface positioned on a surface of the mount in contact with the electrical component.

In various embodiments, the electronic device includes a frame made of a metal material, and at least a portion of an area of the waterproof bracket facing the frame is made of a metal material.

In various embodiments, the electronic device includes a second thermal interface positioned between the waterproof bracket and the frame in the area of the waterproof bracket facing the frame.

In various embodiments, the second thermal interface includes a thermally conductive adhesive tape.

In accordance with another aspect of the disclosure, a waterproof bracket for an electronic device that includes at least one electrical component positioned therein, a button, and a button cable, and provides a waterproof function is provided. The waterproof bracket includes a first surface positioned in an area exposed to moisture introduced from an exterior of the electronic device, a second surface positioned in an area not exposed to moisture, a mount configured such that the electrical component is placed therein, and a cable hole provided through the waterproof bracket from the first surface to the second surface, wherein the cable hole is configured to allow the button cable to pass from the first surface to the second surface.

In various embodiments, the waterproof bracket includes a cable sealing member configured to seal the cable hole.

In various embodiments, the waterproof bracket includes a seal positioned at a boundary between the first surface and the second surface.

In various embodiments, the mount includes a recess having an opening on the second surface and configured to accommodate the electrical component.

In various embodiments, the electrical component includes a directional antenna, and the opening is configured to provide a radiation path along a direction in which the directional antenna radiates a signal.

In various embodiments, at least a portion of an area of the mount in contact with the electrical component is made of a metal material.

In various embodiments, the waterproof bracket includes a first thermal interface positioned on a surface of the mount in contact with the electrical component.

In various embodiments, the electronic device includes a frame made of a metal material, and at least a portion of the area of the waterproof bracket facing the frame is made of a metal material. The waterproof bracket includes a second thermal interface positioned between the waterproof bracket and the frame in the area of the waterproof bracket facing the frame.

According to the disclosure, the waterproof bracket closes an opening of the housing provided for placing a button, thereby maintaining the waterproofness of the housing. In addition, by placing the electrical component in the waterproof bracket, the dead space occupied by the waterproof bracket is reduced.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2A is a front perspective view of an electronic device according to an embodiment of the disclosure;

FIG. 2B is a rear perspective view of the electronic device of FIG. 2A according to an embodiment of the disclosure;

FIG. 3 is an exploded perspective view of the electronic device of FIG. 2A, according to an embodiment of the disclosure;

FIGS. 4A, 4B, 4C, 4D, 4E and 4F illustrate a portable electronic device having an in-folding type housing structure, according to various embodiments of the disclosure;

FIG. 5A is an exploded perspective view illustrating a portion of the electronic device according to an embodiment of the disclosure;

FIG. 5B is a cross-sectional view illustrating a portion of the electronic device according to an embodiment of the disclosure;

FIG. 6A is a perspective view illustrating a waterproof bracket and an electrical component according to an embodiment of the disclosure;

FIG. 6B is a cross-sectional view of an electronic device illustrating the arrangement of the waterproof bracket according to an embodiment of the disclosure;

FIG. 6C is a cross-sectional view illustrating the waterproof bracket according to an embodiment of the disclosure; and

FIG. 6D is a cross-sectional view illustrating the waterproof bracket according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that various embodiments of the disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

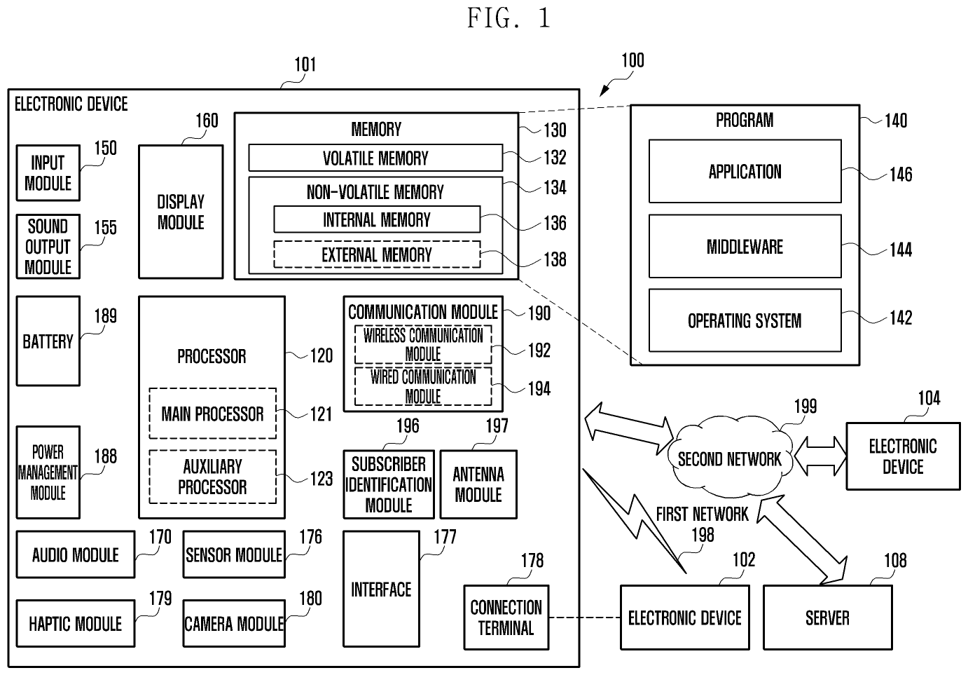

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connection terminal 178, a haptic module 179, a camera module 180, a power management module 188, a battery 189, a communication module 190, a subscriber identification module (SIM) 196, or an antenna module 197. In some embodiments, at least one of the components (e.g., the connection terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connection terminal 178 may include a connector via which the electronic device 101 may be physically connected with the external electronic device (e.g., the electronic device 102). According to an embodiment, the connection terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth-generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth-generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104 or server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

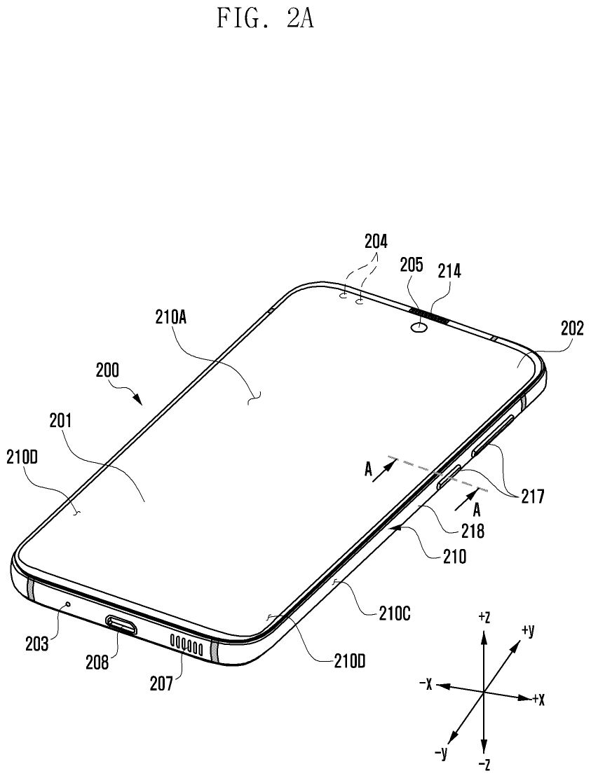

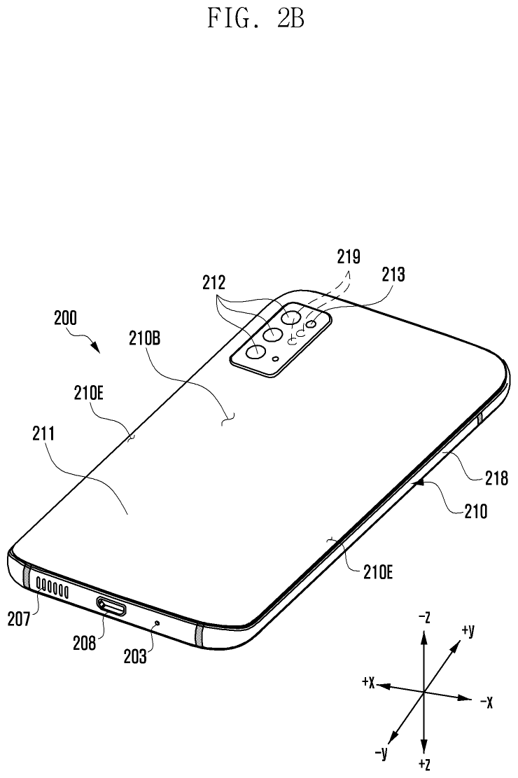

FIG. 2A illustrates a perspective view showing a front surface of a mobile electronic device according to an embodiment of the disclosure.

FIG. 2B illustrates a perspective view showing a rear surface of the mobile electronic device shown in FIG. 2A according to an embodiment of the disclosure.

The electronic device 300 of FIGS. 2Aa and 2B may be at least partially similar to the electronic device 101 of FIG. 1 or may include other embodiments of the electronic device.

Referring to FIGS. 2A and 2B, the mobile electronic device 200 may include a housing 210 that includes a first surface (or front surface) 210A, a second surface (or rear surface) 210B, and a lateral surface 210C that surrounds a space between the first surface 210A and the second surface 210B. The housing 210 may refer to a structure that forms a part of the first surface 210A, the second surface 210B, and the lateral surface 210C. The first surface 210A may be formed of a front plate 202 (e.g., a glass plate or polymer plate coated with a variety of coating layers) at least a part of which is substantially transparent. The second surface 210B may be formed of a rear plate 211 which is substantially opaque. The rear plate 211 may be formed of, for example, coated or colored glass, ceramic, polymer, metal (e.g., aluminum, stainless steel (STS), or magnesium), or any combination thereof. The lateral surface 210C may be formed of a lateral bezel structure (or “lateral member”) 218 which is combined with the front plate 202 and the rear plate 211 and includes a metal and/or polymer. The rear plate 211 and the lateral bezel structure 218 may be integrally formed and may be of the same material (e.g., a metallic material such as aluminum).

The front plate 202 may include two first regions 210D disposed at long edges thereof, respectively, and bent and extended seamlessly from the first surface 210A toward the rear plate 211. Similarly, the rear plate 211 may include two second regions 210E disposed at long edges thereof, respectively, and bent and extended seamlessly from the second surface 210B toward the front plate 202. The front plate 202 (or the rear plate 211) may include only one of the first regions 210D (or of the second regions 210E). The first regions 210D or the second regions 310E may be omitted in part. When viewed from a lateral side of the mobile electronic device 200, the lateral bezel structure 218 may have a first thickness (or width) on a lateral side where the first region 210D or the second region 210E is not included, and may have a second thickness, being less than the first thickness, on another lateral side where the first region 210D or the second region 210E is included.

The mobile electronic device 200 may include at least one of a display 201, audio modules 203, 207 and 214, sensor modules 204 and 219, camera modules 205, 212 and 213, a key input device 217, a light emitting device, and connector holes 208 and 209. The mobile electronic device 200 may omit at least one (e.g., the key input device 217 or the light emitting device) of the above components, or may further include other components.

The display 201 may be exposed through a substantial portion of the front plate 202, for example. At least a part of the display 201 may be exposed through the front plate 302 that forms the first surface 210A and the first region 210D of the lateral surface 210C. Outlines (i.e., edges and corners) of the display 201 may have substantially the same form as those of the front plate 202. The spacing between the outline of the display 201 and the outline of the front plate 202 may be substantially unchanged in order to enlarge the exposed area of the display 201. A recess or opening may be formed in a portion of a display area of the display 201 to accommodate at least one of the audio module 214, the sensor module 204, the camera module 205, and the light emitting device. At least one of the audio module 214, the sensor module 204, the camera module 205, the fingerprint sensor (not shown), and the light emitting element may be disposed on the back of the display area of the display 201. The display 201 may be combined with, or adjacent to, a touch sensing circuit, a pressure sensor capable of measuring the touch strength (pressure), and/or a digitizer for detecting a stylus pen. At least a part of the sensor modules 204 and 219 and/or at least a part of the key input device 217 may be disposed in the first region 210D and/or the second region 210E.

The audio modules 203, 207 and 214 may correspond to a microphone hole 203 and speaker holes 207 and 214, respectively. The microphone hole 203 may contain a microphone disposed therein for acquiring external sounds and, in a case, contain a plurality of microphones to sense a sound direction. The speaker holes 207 and 214 may be classified into an external speaker hole 207 and a call receiver hole 214. The microphone hole 203 and the speaker holes 207 and 314 may be implemented as a single hole, or a speaker (e.g., a piezo speaker) may be provided without the speaker holes 207 and 214.

The sensor modules 204 and 219 may generate electrical signals or data corresponding to an internal operating state of the mobile electronic device 200 or to an external environmental condition. The sensor modules 204 and 219 may include a first sensor module 204 (e.g., a proximity sensor) and/or a second sensor module (e.g., a fingerprint sensor) disposed on the first surface 210A of the housing 210, and/or a third sensor module 219 (e.g., a heart rate monitor (HRM) sensor) and/or a fourth sensor module (e.g., a fingerprint sensor) disposed on the second surface 210B of the housing 210. The fingerprint sensor may be disposed on the second surface 210B as well as the first surface 210A (e.g., the display 201) of the housing 210. The electronic device 200 may further include at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 205, 212 and 213 may include a first camera device 205 disposed on the first surface 210A of the electronic device 200, and a second camera device 312 and/or a flash 213 disposed on the second surface 210B. The camera module 205 or the camera module 212 may include one or more lenses, an image sensor, and/or an image signal processor. The flash 213 may include, for example, a light emitting diode or a xenon lamp. Two or more lenses (infrared cameras, wide angle and telephoto lenses) and image sensors may be disposed on one side of the electronic device 300.

The key input device 217 may be disposed on the lateral surface 210C of the housing 210. The mobile electronic device 200 may not include some or all of the key input device 217 described above, and the key input device 217 which is not included may be implemented in another form such as a soft key on the display 201. The key input device 217 may include the sensor module disposed on the second surface 210B of the housing 210.

The light emitting device may be disposed on the first surface 210A of the housing 210. For example, the light emitting device may provide status information of the electronic device 200 in an optical form. The light emitting device may provide a light source associated with the operation of the camera module 205. The light emitting device may include, for example, a light emitting diode (LED), an IR LED, or a xenon lamp.

The connector holes 208 and 209 may include a first connector hole 208 adapted for a connector (e.g., a USB connector) for transmitting and receiving power and/or data to and from an external electronic device, and/or a second connector hole 309 adapted for a connector (e.g., an earphone jack) for transmitting and receiving an audio signal to and from an external electronic device.

Some sensor modules 205 of camera modules 205 and 212, some sensor modules 204 of sensor modules 204 and 219, or an indicator may be arranged to be exposed through a display 201. For example, the camera module 205, the sensor module 204, or the indicator may be arranged in the internal space of an electronic device 300 so as to be brought into contact with an external environment through an opening of the display 201, which is perforated up to a front plate 202. In another embodiment, some sensor modules 204 may be arranged to perform their functions without being visually exposed through the front plate 202 in the internal space of the electronic device. For example, in this case, an area of the display 201 facing the sensor module may not require a perforated opening.

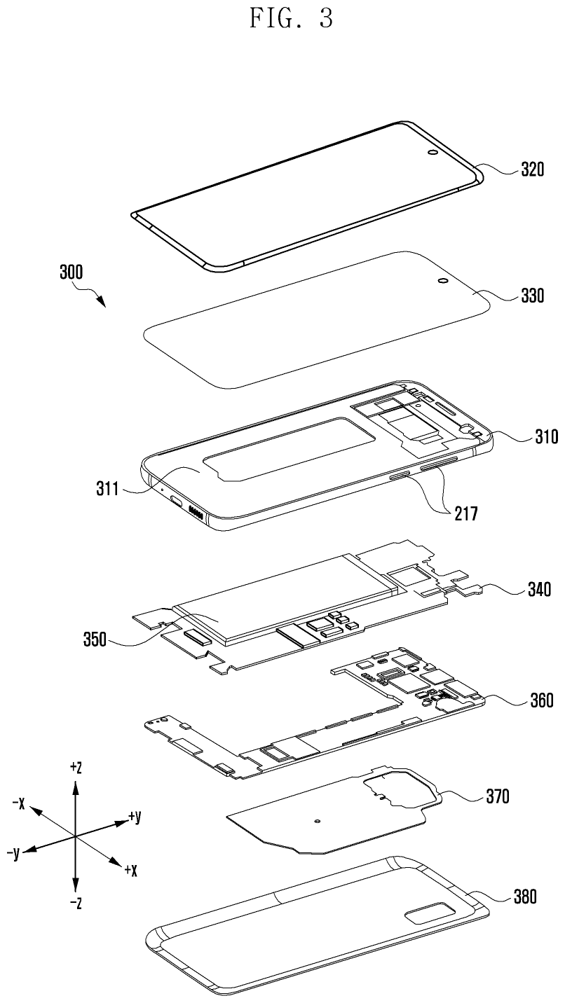

According to an embodiment, the electronic device 200 has a bar-type or plate-type appearance, but the disclosure is not limited thereto. For example, the illustrated electronic device 200 may be a portion of a foldable electronic device, a slidable electronic device, a stretchable electronic device, and/or a rollable electronic device. The terms “foldable electronic device,” “slidable electronic device,” “stretchable electronic device,” and/or “rollable electronic device” may refer to an electronic device in which bending transformation of a display (e.g., the display 330 in FIG. 3) is possible, so that the display can be at least partially folded, wound or rolled, at least partially expanded in area, and/or accommodated inside a housing (e.g., the housing 210 in FIGS. 2A and 2B). The foldable electronic device, the slidable electronic device, the stretchable electronic device, and/or the rollable electronic device may allow a user to use a screen display area in an expanded state by unfolding the display or exposing a greater area of the display to the outside depending on a user's needs.

FIG. 3 is an exploded perspective view of the electronic device of FIG. 2A, according to an embodiment of the disclosure.

The electronic device 300 of FIG. 3 may be at least partially similar to the electronic device 200 of FIGS. 2A and 2B, or may represent another embodiment of the electronic device.

Referring to FIG. 3, the mobile electronic device 300 may include a lateral bezel structure 310, a first support member 311 (e.g., a bracket), a front plate 320, a display 330, an electromagnetic induction panel, a PCB 340, a battery 350, a second support member 360 (e.g., a rear case), an antenna 370, and a rear plate 380. The mobile electronic device 300 may omit at least one (e.g., the first support member 311 or the second support member 360) of the above components or may further include another component. Some components of the electronic device 300 may be the same as or similar to those of the mobile electronic device 300 shown in FIG. 2A or 2B, thus, descriptions thereof are omitted below.

The first support member 311 is disposed inside the mobile electronic device 300 and may be connected to, or integrated with, the lateral bezel structure 310. The first support member 311 may be formed of, for example, a metallic material and/or a non-metal (e.g., polymer) material. The first support member 311 may be combined with the display 301 at one side thereof and also combined with the PCB 340 at the other side thereof. On the PCB 340, a processor, memory, and/or an interface may be mounted. The processor may include, for example, one or more of a CPU, an AP, a GPU, an ISP, a sensor hub processor, or a CP.

The memory may include, for example, volatile memory or non-volatile memory.

The interface may include, for example, a high definition multimedia interface (HDMI), a USB interface, a secure digital (SD) card interface, and/or an audio interface. The interface may electrically or physically connect the mobile electronic device 300 with an external electronic device and may include a USB connector, an SD card/multimedia card (MMC) connector, or an audio connector.

The battery 350 is a device for supplying power to at least one component of the mobile electronic device 300, and may include, for example, a non-rechargeable primary battery, a rechargeable secondary battery, or a fuel cell. At least a part of the battery 350 may be disposed on substantially the same plane as the PCB 340. The battery 350 may be integrally disposed within the mobile electronic device 300, and may be detachably disposed from the mobile electronic device 300.

The antenna 370 may be disposed between the rear plate 380 and the battery 350. The antenna 370 may include, for example, a near field communication (NFC) antenna, a wireless charging antenna, and/or a magnetic secure transmission (MST) antenna. The antenna 370 may perform short-range communication with an external device, or transmit and receive power required for charging wirelessly. An antenna structure may be formed by a part or combination of the lateral bezel structure 310 and/or the first support member 311.

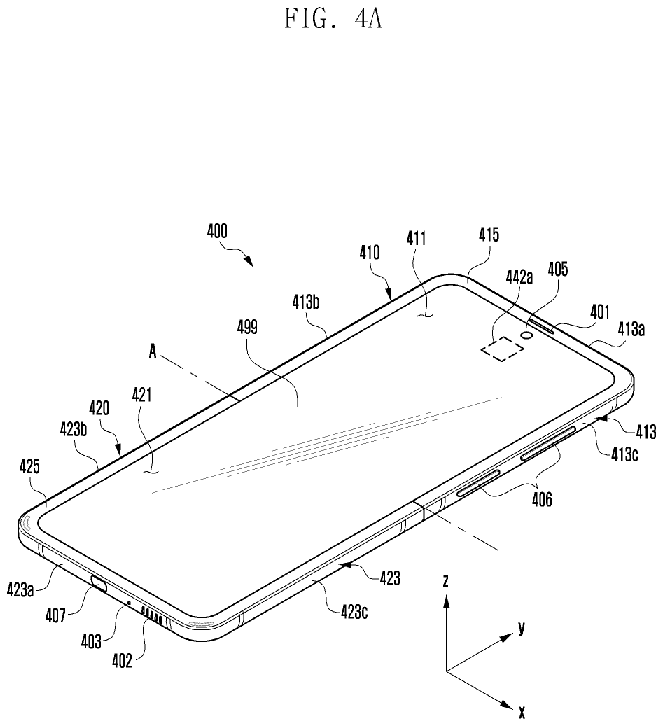

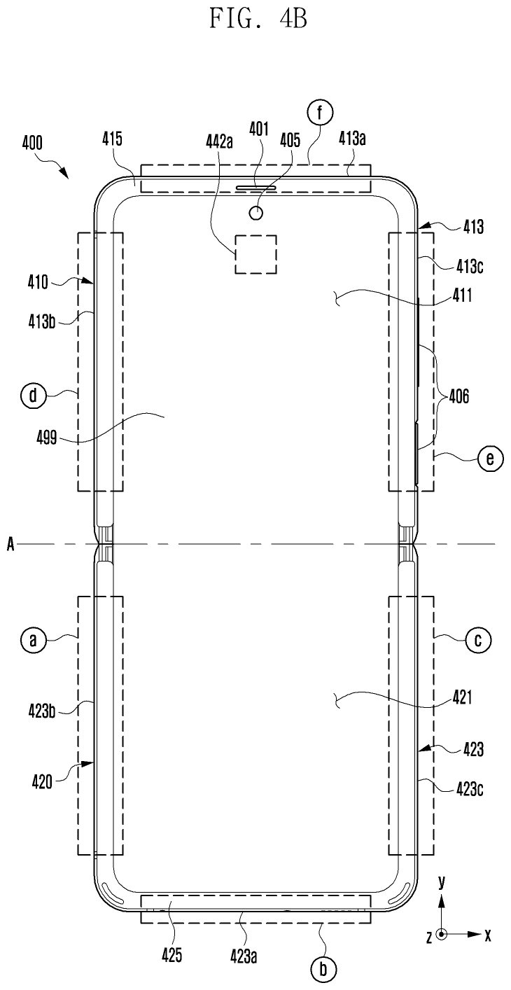

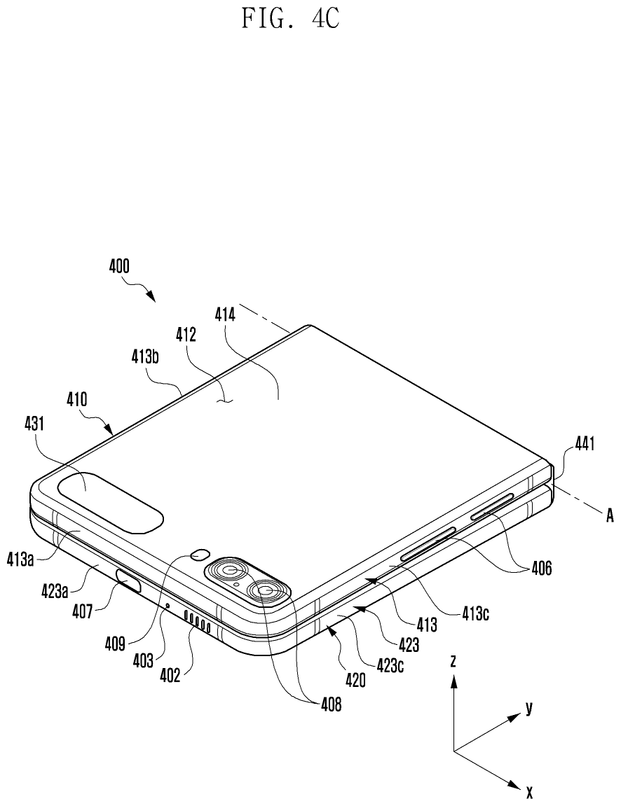

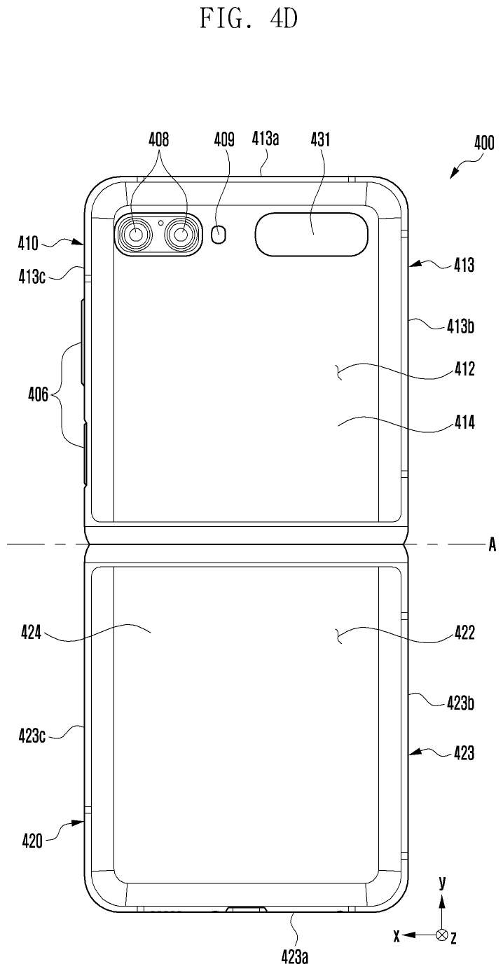

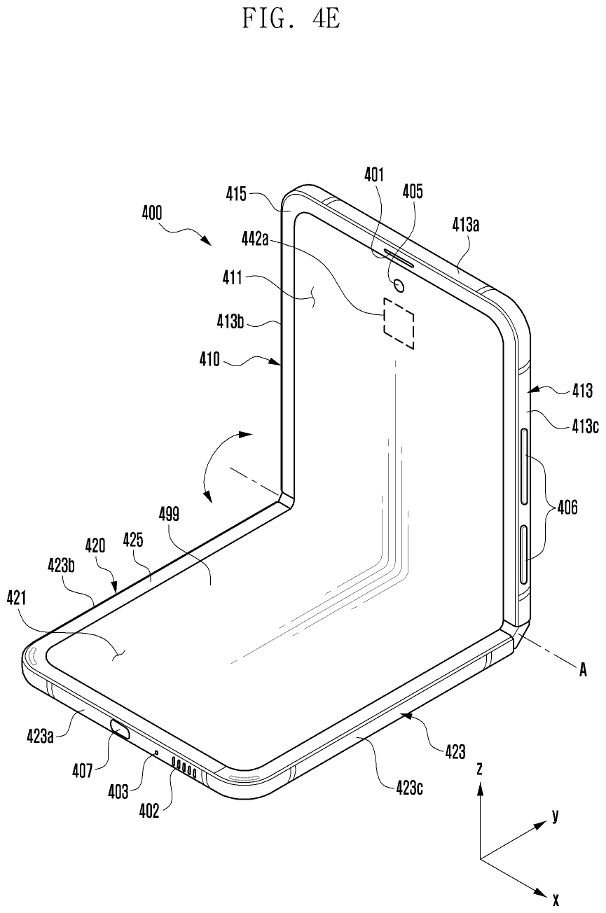

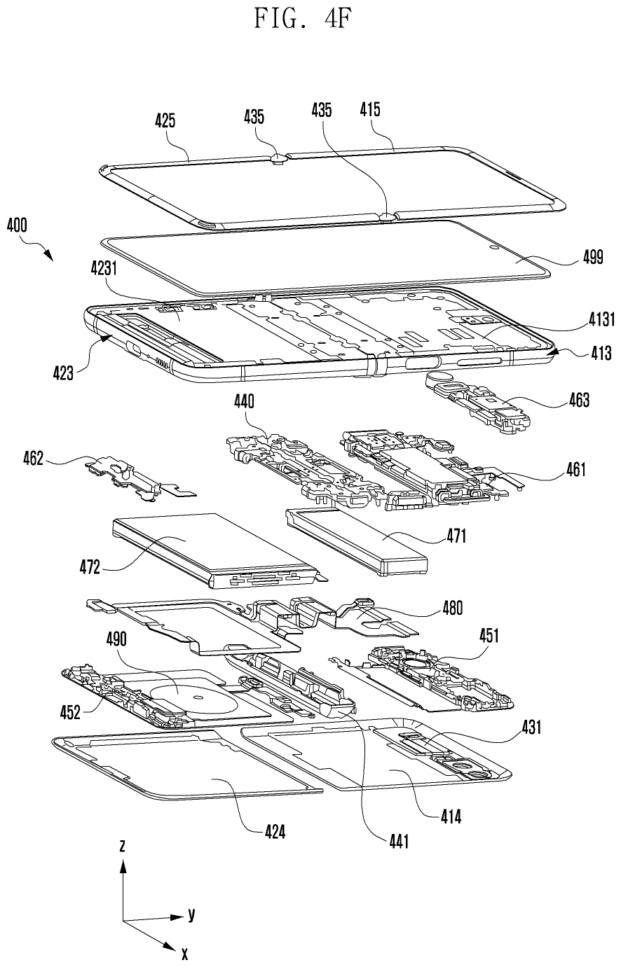

FIGS. 4A, 4B, 4C, 4D, 4E, and 4F illustrate a portable electronic device 400 having an in-folding type housing structure, according to various embodiments of the disclosure.

Referring to FIGS. 4A and 4B illustrate the front surface of a foldable portable electronic device (hereinafter, simply referred to as an electronic device) in an unfolded (or flat or open) state according to various embodiments, FIG. 4C illustrates the rear surface of the electronic device in a folded (or closed) state, FIG. 4D illustrates a rear view of the electronic device in an unfolded state, FIG. 4E illustrates a front surface of the electronic device in a partially folded state, in other words, a partially unfolded state or an intermediate state (freestop state) between the fully folded state and the fully unfolded state, and FIG. 4F is an exploded perspective view of the electronic device.

Referring to FIGS. 4A, 4B, 4C, 4D, 4E, and 4F, a portable electronic device 400 (e.g., the electronic device 101 in FIG. 1) may include a first housing 410, a second housing 420, a hinge assembly 440 interconnecting the first housing 410 and the second housing 420 such that the second housing 420 is rotatable relative to the first housing 410, a flexible or foldable display 499 disposed in a space defined by the foldable housings 410 and 420, and a sensor module (e.g., the sensor module 176 in FIG. 1).

The display 499 may be disposed from the first housing 410 to the second housing 420 across the hinge assembly 440. The display 499 may be divided into a first display area 411 disposed in the inner space of the first housing 410 and a second display area 421 disposed in the inner space of the second housing 420 with reference to the folding axis A. The sensor module (e.g., an illuminance sensor) may be disposed under a sensor area (or a light transmission area) 442a of the first display area 411 when the front surface is viewed from the front side. The location and/or size of the sensor area 442a in the first display area 411 may be determined by the location and/or size of the illuminance sensor disposed thereunder. For example, the size (e.g., the diameter) of the sensor area 442a may be determined based on a field of view (FOV) of the illuminance sensor. In an embodiment, the sensor area 442a may be configured to have a lower pixel density and/or a lower wiring density than that in the periphery thereof to improve light transmittance. In some embodiments, the display 499 may include a transparent material and a protective layer 498 configured to protect a panel layer from external foreign substances and impacts.

The hinge assembly 440 may be implemented in an in-folding type which causes the two display areas 411 and 421 to face each other when the portable electronic device 400 is transitioned from the unfolded state (e.g., the state in FIG. 4A) to the folded state (e.g., the state in FIG. 4C). For example, when the electronic device 400 is in the unfolded state, the two display areas 411 and 421 may face substantially the same direction. As the state is changed from the unfolded state to the folded state, the two display areas 411 and 421 may be rotated to a direction in which the two display areas face each other. The hinge assembly 440 may be configured such that the foldable housings 410 and 420 have resistance to rotation. When an external force exceeding the resistance is applied to the foldable housings 410 and 420, the foldable housings 410 and 420 may be rotated.

Based on the angle formed between the two display areas 411 and 421, the state of the electronic device 400 may be defined. For example, the state of the electronic device 400 may be defined as an unfolded (unfolded, flat, or open) state when the angle between the two display areas 411 and 421 is about 180 degrees. When the angle between the two display areas 411 and 421 is between about 0 and 10 degrees, the state of the portable electronic device 400 may be defined as a folded or closed state. When the two display areas 411 and 421 form an angle greater than the angle in the folded state and smaller than the angle in the unfolded state (e.g., between about 10 degrees and 179 degrees), the state of the portable electronic device 400 may be defined as an intermediate state (in other words, a partially folded or partially unfolded state) as illustrated in FIG. 4E.

An active area in which visual information (e.g., text, image, or icon) is to be displayed on the display 499 may be determined based on the state of the portable electronic device 400. For example, when the electronic device 400 is in the intermediate state, the active area may be determined as the first display area 411 or the second display area 421. Of the first display area 411 and the second display area 421, an area having a relatively smaller movement may be determined as the active area. For example, when the user holds a housing of the electronic device 400 with one hand and opens another housing with a finger (e.g., the thumb) of the same hand or the other hand, the electronic device 400 may be transitioned from the folded state to the intermediate state, and as a result, in the electronic device 400, the display area of the held housing (i.e., the housing having a relatively smaller movement) may be determined as the active area. When the portable electronic device 400 is in the unfolded state, the entire area of the display 499 (e.g., both the first display area 411 and the second display area 421) may be determined as the active area.

According to various embodiments, in the unfolded state, the first housing 410 may include a first surface (a first display area) 411 oriented in a first direction (e.g., the front direction) (the z-axis direction) and a second surface 412 oriented in a second direction (e.g., a rear direction) (the −z-axis direction) in which the second surface faces away from the first surface 411. In the unfolded state, the second housing 420 may include a third surface (a second display area) 421 oriented in the first direction (e.g., the z-axis direction) and a fourth surface 422 oriented in the second direction (e.g., the −z-axis direction). The electronic device 400 may be operate such that, in the unfolded state, the first surface 411 of the first housing 410 and the third surface 421 of the second housing 420 are oriented in the same first direction (e.g., the z-axis direction), and, in the folded state, the first surface 411 and the third surface 421 face each other. The electronic device 400 may be operated such that, in the unfolded state, the second surface 412 of the first housing 410 and the fourth surface 422 of the second housing 420 are oriented in the same second direction (the −z-axis direction), and, in the folded state, the second surface 412 and the fourth surface 422 face away from each other.

According to various embodiments, the first housing 410 may include a first side surface frame 413 defining at least a portion of the exterior of the electronic device 400 and a first rear surface cover 414 coupled to the first side surface frame 413 and defining at least a portion of the second surface 412 of the electronic device 400. According to an embodiment, the first side surface frame 413 may include a first side surface 413a, a second side surface 413b extending from one end of the first side surface 413a, and a third side surface 413c extending from the other end of the first side surface 413a. According to an embodiment, the first side surface frame 413 may have a rectangular (e.g., square or oblong) shape configured with the first side surface 413a, the second side surface 413b, and the third side surface 413c.

A portion of the first side surface frame 413 may be formed of a conductor. For example, referring to FIG. 4B, a portion f) of the first side surface 413a, a portion @ of the second side surface 413b, and a portion e of the third side surface 413c may be made of a metal material. The conductors may be electrically connected to grip sensors (not illustrated), respectively, which are disposed in the inner space of the first housing 410 adjacent thereto. A processor may measure the capacitances formed between the conductors and a ground (e.g., a ground of a main printed circuit board) via the grip sensors, and may recognize that a dielectric body (e.g., a finger, a palm, or a face) is close to (or in contact with) the first housing 410 and a place that is contact with the dielectric body in the first housing 410 (e.g., the first side surface 413a, the second side surface 413b, or the third side surface 413c) based on the measured capacitance values.

According to various embodiments, the second housing 420 may include a second side surface frame 423 defining at least a portion of the exterior of the electronic device 400 and a second rear surface cover 424 coupled to the second side surface frame 423 and defining at least a portion of the fourth surface 422 of the electronic device 400. According to an embodiment, the second side surface frame 423 may include a fourth side surface 423a, a fifth side surface 423b extending from one end of the fourth side surface 423a, and a sixth side surface 423c extending from the other end of the fourth side surface 423b. According to an embodiment, the second side surface frame 423 may be provided in a rectangular shape by the fourth side surface 423a, the fifth side surface 423b, and the sixth side surface 423c.

A portion of the first side surface frame 423 may be formed of a conductor. For example, referring to FIG. 4B, a portion \textcircled{b} of the fourth side surface 423a, a portion \textcircled{a} of the fifth side surface 423b, and a portion \textcircled{b} of the sixth side surface 423c may be formed of a metal material. The conductors may be electrically connected to grip sensors (not illustrated), respectively, which are disposed in the inner space of the second housing 420 adjacent thereto. A processor may measure the capacitance formed between the conductors and a ground (e.g., a ground of a main printed circuit board) via the grip sensors, and may recognize that a dielectric body is close to (or in contact with) the second housing 420 and a place that is contact with the dielectric body in the second housing 420 (e.g., the fourth side surface 423a, the fifth side surface 423b, or the sixth side surface 423c) based on the measured capacitance values.

According to various embodiments, the pair of housing structures 410 and 420 are not limited to the illustrated shape and assembly, but may be implemented by other shapes or other combinations and/or assemblies of components. For example, the first side surface frame 413 and the first rear surface cover 414 may be integrally configured, and the second side surface frame 423 and the second rear surface cover 424 may be integrally configured.

According to various embodiments, the first rear surface cover 414 and the second rear surface cover 424 may be made of at least one of, for example, coated or colored glass, ceramic, polymer, or metal (e.g., aluminum, stainless steel (STS), or magnesium) or a combination of at least two of these materials.

According to various embodiments, the electronic device 400 may include a first protective cover 415 (e.g., a first protective frame or a first decoration member) coupled along the periphery of the first housing 410. The electronic device 400 may include a second protective cover 425 (e.g., a second protective frame or a second decoration member) coupled along the periphery of the second housing 420. According to an embodiment, the first protective cover 415 and the second protective cover 425 may be made of a metal or polymer material.

According to various embodiments, the electronic device 400 may include a sub-display 431 disposed separately from the display 499. According to an embodiment, the sub-display 431 is disposed to be at least partially exposed on the second surface 412 of the first housing 410, so that when the electronic device 400 is in a folded state, the sub-display 231 may display state information of the electronic device 200. According to an embodiment, the sub-display 431 may be disposed to be visible from the outside through at least a partial area in the first rear surface cover 414. In some embodiments, the sub-display 431 may be disposed on the fourth surface 424 of the second housing 420. In this case, the sub-display 431 may be disposed to be visible from the outside through at least a partial area of the second rear surface cover 424.

According to various embodiments, the electronic device 400 may include at least one of an input device 403, a sound output device 401 or 402, a camera module 405 or 408 and/or a flash 409 that are disposed through the second surface 412 (e.g., the first rear cover 414) of the first housing 410 a key input device 406, a connector port 407, and a sensor module (not illustrated). In an embodiment, the sensor module (e.g., the sensor module 176 in FIG. 1), and the camera 405 may be disposed below the display 499 when the front surface is viewed from the front side.

According to various embodiments, the electronic device 400 may be operated to maintain the intermediate state via the hinge assembly 440. In this case, the electronic device 400 may control the display 499 to display different contents on the display area corresponding to the first surface 411 and the display area corresponding to the third surface 421, respectively.

Referring to FIG. 4F, the electronic device 400 according to various embodiments may include a first side surface frame 413, a second side surface frame 423, and a hinge assembly 440 rotatably connecting the first side surface frame 413 and the second side surface frame 423 to each other. According to an embodiment, the electronic device 400 may include a first support plate 4131 at least partially extending from the first side surface frame 413 and a second support plate 4232 at least partially extending from the second side surface frame 423. According to an embodiment, the first support plate 4131 may be integrally formed with the first side surface frame 413 or may be structurally coupled to the first side surface frame 413. Similarly, the second support plate 4232 may be integrally formed with the second side surface frame 423 or may be structurally coupled to the second side surface frame 423. According to an embodiment, the electronic device 400 may include a display 499 disposed to be supported by the first support plate 4131 and the second support plate 4232. According to an embodiment, the electronic device 400 may include a first rear surface cover 414 coupled to the first side surface frame 413 and providing a first space with the first support plate 4131, and a second rear surface cover 424 coupled to the second side surface frame 423 and providing a second space with the second support plate 4232. In some embodiments, the first side surface frame 413 and the first rear surface cover 414 may be integrated. In some embodiments, the second side surface frame 423 and the second rear surface cover 424 may be integrally formed. According to an embodiment, the electronic device 400 may include a first housing 410 provided via the first side surface frame 413, the first support plate 4131, and the first rear surface cover 414. According to an embodiment, the electronic device 400 may include a second housing 420 provided via the second side surface frame 423, the second support plate 4232, and the second rear surface cover 424.

Although not illustrated, the hinge assembly 440 may include a first arm structure coupled to the first housing 410 (e.g., the first support plate 4231), a second arm structure coupled to the second housing 420 (e.g., the second support plate 4232), and a detent structure that is in physical contact with the first arm structure and the second arm structure such that the first housing 410 and the second housing 420 have resistance to rotation. The foldable housings 410 and 420 may have resistance to rotation by the contact force of the detent structure (e.g., the force pushing the first arm structure and the second arm structure).

According to various embodiments, the electronic device 400 may include a first board assembly 461 (e.g., a main printed circuit board), a camera assembly 463, a first battery 471, or a first bracket 451 disposed in a first space between the first side surface frame 413 and the first rear surface cover 414. According to an embodiment, the camera assembly 463 may include a plurality of cameras (e.g., the camera modules 405 and 408 in FIGS. 4A and 4C), and may be electrically connected to the first board assembly 461. According to an embodiment, the first bracket 451 may provide a support structure for supporting the first board assembly 461 and/or the camera assembly 463 and improved rigidity. According to an embodiment, the electronic device 400 may include a second board assembly 462 (e.g., a sub printed circuit board), an antenna 490 (e.g., a coil member), a second battery 472, or a second bracket 452 disposed in a second space between the second side surface frame 423 and the second rear surface cover 424. According to an embodiment, the electronic device 400 may include a wiring member 480 (e.g., a flexible printed circuit board (FPCB)) disposed to extend from the first board assembly 461 across the hinge assembly 440 to a plurality of electronic components (e.g., the second board assembly 462, the second battery 472, or the antenna 490) disposed between the second side surface frame 423 and the second rear surface cover 424 and to provide an electrical connection.

According to various embodiments, the electronic device 400 may include a hinge cover 441, which is configured to support the hinge assembly 440, exposed to the outside when the electronic device 400 is in the folded state, and introduced into the first space and the second space to be invisible from the outside when the electronic device 200 is in the unfolded state.

According to various embodiments, the electronic device 400 may include a first protective cover 415 coupled along the edges of the first side surface frame 413. According to an embodiment, the electronic device 400 may include a second protective cover 425 coupled along the edges of the second side surface frame 423. In the display 499, the edges of the first display area 411 may be protected by the first protective cover 415. The edges of the second display area 421 may be protected by the second protective cover 425. Protective caps 435 may be disposed in an area corresponding to the hinge assembly 440 to protect bent portions of the edges of the display 499.

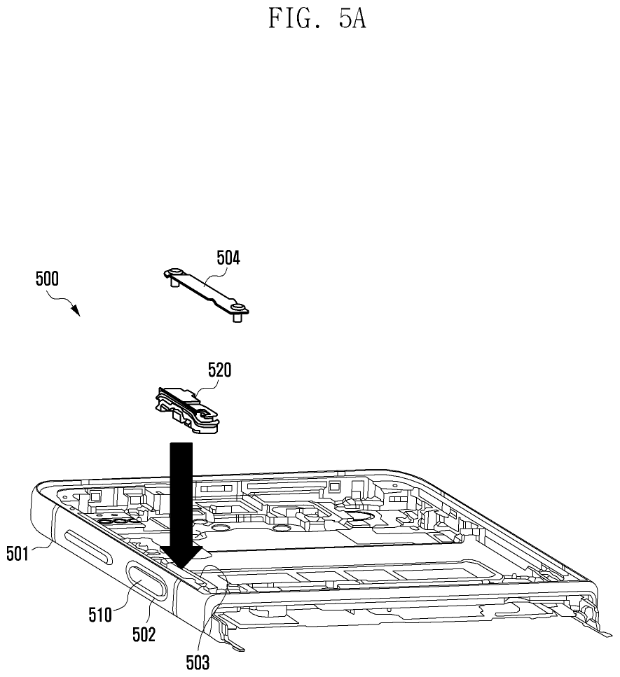

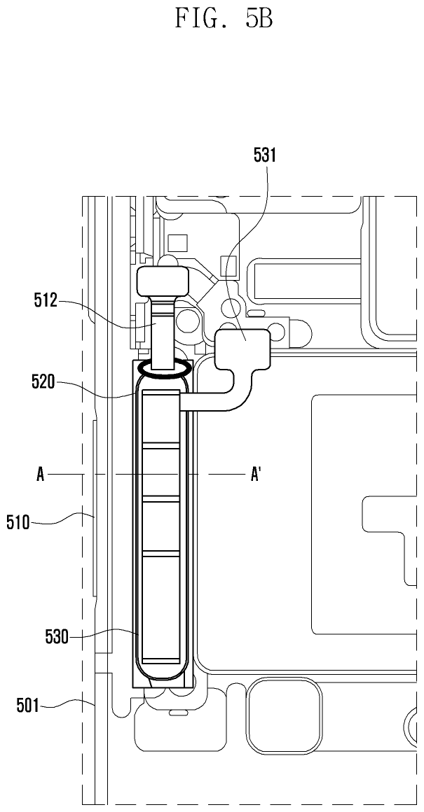

FIG. 5A is an exploded perspective view illustrating a portion of the electronic device according to an embodiment of the disclosure.

FIG. 5B is a cross-sectional view illustrating a portion of the electronic device according to an embodiment of the disclosure.

Referring to FIGS. 5A and 5B, an electronic device (e.g., the electronic device 101 of FIG. 1, the electronic device 200 of FIGS. 2A, 2B and 3, and the electronic device 400 of FIGS. 4A, 4B, 4C, 4D, 4E, and 4F) according to various embodiments of the disclosure may include a button 510 and a waterproof bracket 520. The button 510 may include an input device that is physically operated by a user to adjust various functions such as power, volume, or an AI assistant of the electronic device 500. In various embodiments, the button 510 may be integrated with a biometric sensor, such as a fingerprint sensor. For example, as illustrated in the drawings described later, the button 510 may be a button module 510 in which components such as a key 511, a fingerprint sensor 513 disposed on a surface of the key 511, a circuit board 514 driving the fingerprint sensor 513, a switch 515, and a button cable 512 are modularized and integrated. In various embodiments, the button module 510 may be waterproofed to prevent internal components from being damaged by moisture.

In various embodiments, a housing 501 (e.g., the housing 210 of FIGS. 2A, 2B and 3) of the electronic device 500 may have a button hole 502. During the assembly of the electronic device 500, the button 510 may be inserted from the interior of the electronic device and exposed to the exterior of the housing 501 of the electronic device 500 through the button hole 502. For example, since the button module 510 integrates each component into a single module, it may be difficult to separately assemble a key and a switch from the interior and the exterior of the housing 501 of the electronic device 500. Accordingly, the button module 510 may be assembled from the interior of the electronic device 500.

The waterproof bracket 520 may be a member that blocks or reduces the inflow of liquid impurities, such as moisture, introduced through the button hole 502. In various embodiments, the waterproof bracket 520 may be fixed to the housing 501 and/or the frame 503 of the electronic device 500 by a fixing member 504. A detailed configuration of the waterproof bracket 520 will be described later.

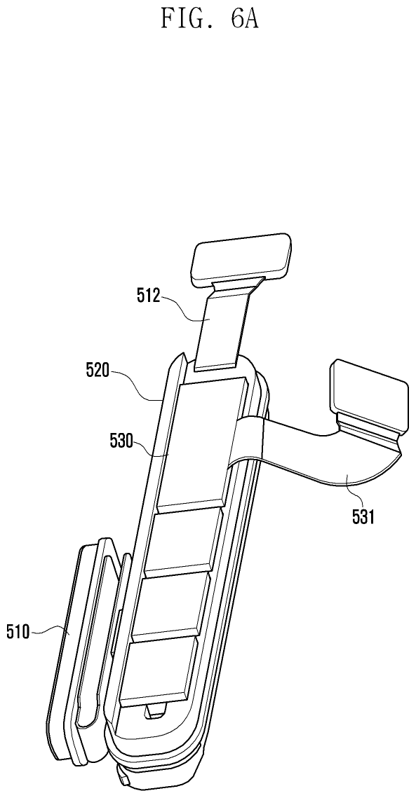

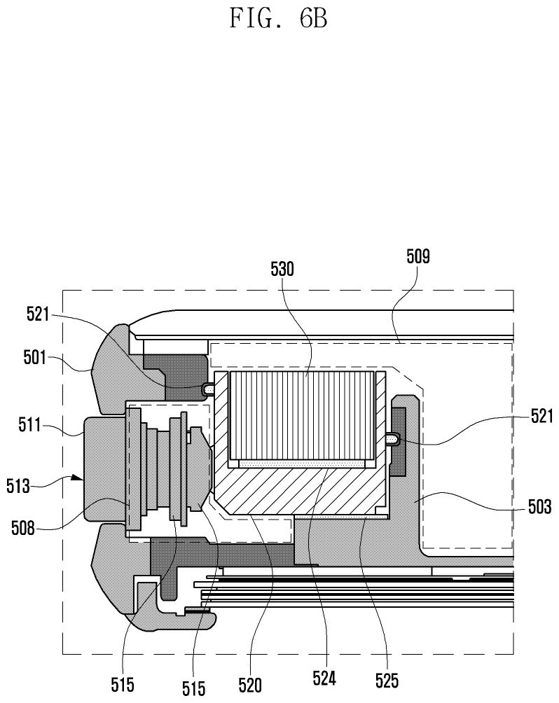

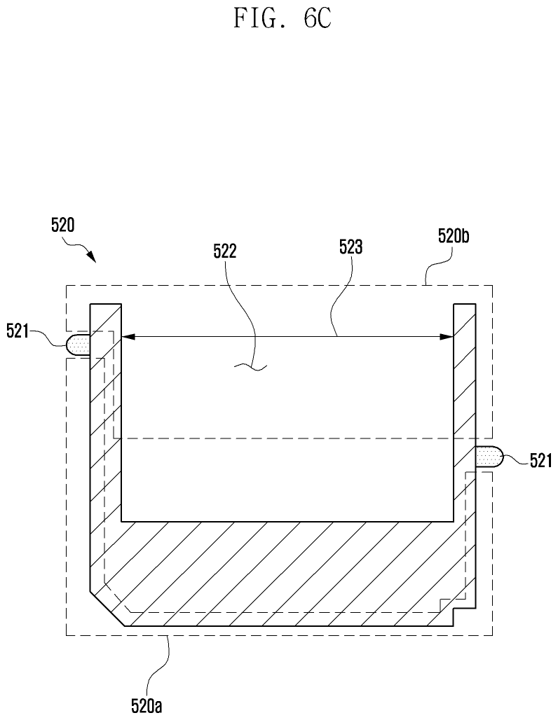

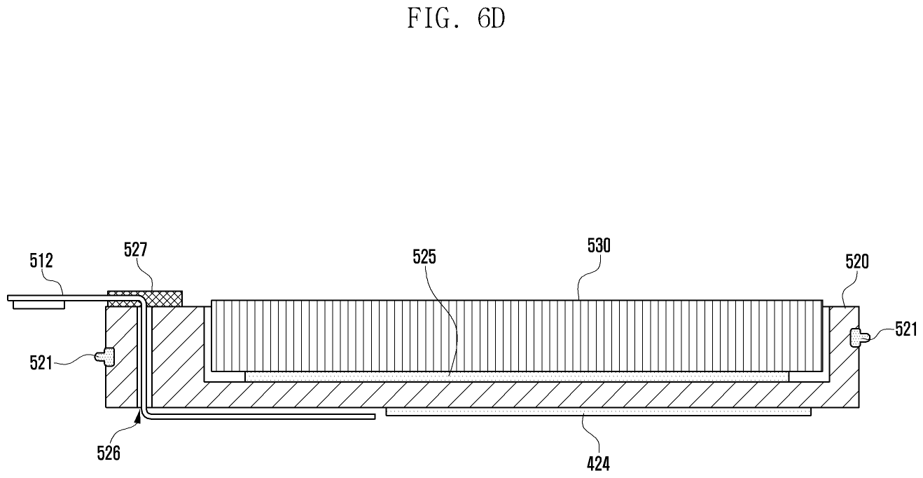

FIG. 6A is a perspective view illustrating a waterproof bracket and an electrical component according to an embodiment of the disclosure.

FIG. 6B is a cross-sectional view of an electronic device illustrating the arrangement of the waterproof bracket according to an embodiment of the disclosure.

FIG. 6C is a cross-sectional view illustrating the waterproof bracket according to an embodiment of the disclosure.

FIG. 6D is a cross-sectional view illustrating the waterproof bracket according to an embodiment of the disclosure.

The cross-sections of FIGS. 6B and 6C correspond to a cutting plane taken along direction A-A′ of FIG. 5B, and the cross-section of FIG. 6D corresponds to a cutting plane taken along direction B-B′ of FIG. 6A.

Referring to FIGS. 6A and 6B, the electronic device 500 may include the waterproof bracket 520. The waterproof bracket 520 may be a member that blocks or reduces the inflow of liquid impurities, such as moisture, introduced through the button hole 502. In various embodiments, the electronic device 500 may have a floodable area 508 in which liquid inflow from the exterior is allowed and a watertight area 509 in which liquid inflow is blocked. The waterproof bracket 520 may be positioned between the floodable area 508 and the watertight area 509 and may serve as a member that blocks or reduces the penetration of external liquid introduced through the button hole 502 into the watertight area 509. The waterproof bracket 520 may have a first surface 520a, which is a surface exposed to external liquid, and a second surface 520b, which is an area not exposed to external liquid, depending on whether or not the waterproof bracket is exposed to liquid introduced from the exterior. For example, the first surface 520a may be positioned in the floodable area 508 of the electronic device 500 described above, and the second surface 520b may be positioned in the watertight area 509 of the electronic device 500.

In various embodiments, the waterproof bracket 520 may include a seal 521. The seal 521 may be disposed along the boundary between the first surface 520a and the second surface 520b on the outer periphery of the waterproof bracket 520. The seal 521 may be in contact with, for example, the housing 501 and the frame 503 (e.g., the first support member 311 and/or the second support member 360 of FIG. 3) of the electronic device 500 and may serve as a member that blocks or prevents liquid from flowing from the floodable area 508 into the watertight area 509 of the electronic device 500.

In various embodiments, the electronic device 500 may include an electrical component 530. The electrical component 530 may include various electrical components 530 disposed inside the electronic device 500, such as a communication module (e.g., the communication module 190 of FIG. 1) and/or an antenna 530 (e.g., the antenna module 197 of FIG. 1).

In various embodiments, the electrical component 530 may include a directional antenna 530. The directional antenna 530 may include, for example, a patch antenna in which a feeding structure and a plurality of radiation elements are printed on a dielectric substrate (e.g., a printed circuit board and/or a flexible printed circuit board). The directional antenna 530 may include, for example, an antenna 530 configured to perform communication in an NR/FR2 (also referred to as mmWave) frequency band in which beamforming according to the 5G communication standard is performed, for example, a 28 GHz band. In another embodiment, the directional antenna 530 may include an antenna 530 configured to perform beamforming as defined by standards such as IEEE 802.11ac or IEEE 802.11ax. In various embodiments, the electrical component 530 may include a cable 531. The cable 531 may include, for example, a flexible printed circuit (FPC) cable.

Referring to FIG. 6C, in various embodiments, the waterproof bracket 520 may include a mount 522. The mount 522 may be a portion of the waterproof bracket 520 configured to place the electrical component 530 therein. For example, the mount 522 may include a mount recess 522 where a portion of the waterproof bracket 520 is recessed. In various embodiments, the mount recess 522 may have an opening 523. The opening 523 may be provided to open toward a surface of the waterproof bracket 520 positioned in the watertight area 509, that is, on the second surface.

Referring again to FIG. 6B, at least a portion of an area of the waterproof bracket 520 in contact with the electrical component 530 (e.g., the mount 522) may be made of a metal material. The metal material may absorb and transfer heat generated by the electrical component 530 to suppress a temperature increase caused by heat generated by the electrical component 530. In some embodiments, a first thermal interface 524 may be positioned on the surface in contact with the electrical component 530 to transfer heat generated by the electrical component 530 to the waterproof bracket 520. The first thermal interface 524 may include, for example, a thermally conductive tape or thermal paste. In some embodiments, the thermally conductive member may include a thermally conductive adhesive tape, and the thermally conductive adhesive tape may fix the electrical component 530 to the mount 522.

In various embodiments, the waterproof bracket 520 may be in direct or indirect contact with the frame 503 of the electronic device 500. At least a portion of the area of the waterproof bracket 520 in contact with the frame 503 of the electronic device 500 may be made of a metal material. The metal material may disperse heat transferred from the electrical component 530 to the waterproof bracket 520 toward the frame 503, thereby suppressing a temperature increase caused by heat generation in the electrical component 530. In some embodiments, the waterproof bracket 520 may be made of a composite material of metal and a synthetic resin injection-molded material. In other embodiments, the waterproof bracket 520 may be entirely formed of a metal material.

In various embodiments, a second thermal interface 524 may be positioned between the waterproof bracket 520 and the electronic device 500. The second thermal interface 524 may include, for example, a thermally conductive tape or thermal paste. In some embodiments, the thermally conductive member may include a thermally conductive adhesive tape, and the thermally conductive adhesive tape may secure the waterproof bracket 520 to the frame 503.

In various embodiments, the directional antenna 530 may be configured to emit and/or receive radio waves in a direction in which the opening 523 is formed in the mount 522 (e.g., the mount recess 522). The opening 523 may be provided to create a radiation path in the direction in which the directional antenna 530 emits and/or receives radio waves. When the waterproof bracket 520 includes a metal material, the metal material of the waterproof bracket 520 may interfere with transmission and reception of the antenna 530. However, when the directional antenna 530 is arranged to be directed toward the opening 523, interference with the transmission/reception of radio waves of the antenna 530 by the waterproof bracket 520 may be prevented or minimized.

Referring to FIG. 6D, the waterproof bracket 520 may include a cable hole 526. The cable hole 526 may be provided through the waterproof bracket 520 from the first surface to the second surface. The cable hole 526 may be configured to allow a cable, such as the button cable 512 of the button 510 positioned in the floodable area 508 of the electronic device 500, to pass therethrough.

In various embodiments, a waterproofed button module 510 may be positioned in the floodable area 508 of the electronic device 500. An input signal generated by the operation of the button module 510 (e.g., a power on/off signal and/or a fingerprint sensor signal) may be electrically connected to another electrical component 530 (e.g., the PCB 340 of FIG. 3) positioned in the watertight area of the electronic device 500 through the button cable 512.

In various embodiments, the waterproof bracket 520 may include a cable sealing member 527 configured to seal the cable hole 526. The cable sealing member 527 may include, for example, a waterproof tape that covers and seals the cable hole 526. Although not illustrated, in another embodiment, the sealing of the cable hole 526 may be achieved by a waterproof adhesive applied inside the cable hole 526. Accordingly, the inflow of external liquid into the watertight area of the electronic device 500 through the cable hole 526 may be prevented or minimized.

An electronic device 500 according to various embodiments of the disclosure may be an electronic device 500 including at least one electrical component 530. The electronic device 500 may include a button 510 exposed to the exterior of the electronic device 500 and configured to receive an input from a user, a button cable 512 electrically connected to the button 510 and configured to transmit an input signal of the button 510, and a waterproof bracket 520 having a first surface 520a positioned in an area exposed to moisture introduced from the exterior of the electronic device 500 and a second surface 520b positioned in an area not exposed to moisture. The waterproof bracket 520 may include a mount 522 configured such that the electrical component 530 is placed therein and a cable hole 526 provided through the waterproof bracket 520 from the first surface 520a to the second surface 520b. The button cable 512 may extend through the cable hole 526 toward the position of the second surface 520b.

In various embodiments, the waterproof bracket 520 may include a cable sealing member 527 sealing the cable hole 526.

In various embodiments, the waterproof bracket 520 may include a seal positioned at a boundary between the first surface 520a and the second surface 520b.

In various embodiments, the mount 522 may include a mount recess 522 having an opening 523 on the second surface 520b and configured to accommodate the electrical component 530.

In various embodiments, the electrical component 530 may include a cable 531 extending from the mount recess 522 to the interior of the electronic device 500 through the opening 523.

In various embodiments, the electrical component 530 may include a directional antenna 530, and the directional antenna 530 may be configured to radiate a signal toward the opening 523.

In various embodiments, at least a portion of an area of the mount 522 in contact with the electrical component 530 may be made of a metal material.

In various embodiments, the electronic device 500 may include a first thermal interface 524 positioned on a surface of the mount 522 in contact with the electrical component 530.

In various embodiments, the electronic device 500 may include a frame 503 made of a metal material, and at least a portion of an area of the bracket facing the frame 503 may be made of a metal material.

In various embodiments, the electronic device 500 may include a second thermal interface 525 positioned between the bracket and the frame 503 in the area where the bracket faces the frame 503.

In various embodiments, the second thermal interface 525 may include a thermally conductive adhesive tape.

A waterproof bracket 520 according to various embodiments of the disclosure is a waterproof bracket 520 for an electronic device 500 that includes at least one electrical component 530 positioned therein, a button 510, and a button cable 512 and provides a waterproof function. The waterproof bracket 520 may include a first surface 520a positioned in an area exposed to moisture introduced from an exterior of the electronic device 500, a second surface 520b positioned in an area not exposed to moisture, a mount 522 configured such that the electrical component 530 is placed therein, and a cable hole 526 provided through the waterproof bracket 520 from the first surface 520a to the second surface 520b. The cable hole 526 may be configured to allow the button cable 512 to pass from the first surface 520a to the second surface 520b.

In various embodiments, the waterproof bracket 520 may include a cable sealing member 527 sealing the cable hole 526.

In various embodiments, the waterproof bracket 520 may include a seal positioned at a boundary between the first surface 520a and the second surface 520b.

In various embodiments, the mount 522 may include a mount recess 522 having an opening 523 on the second surface 520b and configured to accommodate the electrical component 530.

In various embodiments, the electrical component 530 may include a directional antenna 530, and the opening 523 may be configured to form a radiation path in a direction in which the directional antenna 530 radiates a signal.

In various embodiments, at least a portion of an area of the mount 522 in contact with the electrical component 530 may be made of a metal material.

In various embodiments, the waterproof bracket 520 may include a first thermal interface 524 positioned on a surface of the mount 522 in contact with the electrical component 530.

In various embodiments, the electronic device 500 may include a frame 503 formed of a metal material, and at least a portion of an area of the waterproof bracket 520 facing the frame 503 may be made of a metal material. The waterproof bracket 520 may include a second thermal interface 525 positioned on the surface of the waterproof bracket facing the frame 503.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
at least one electrical component;
a button exposed to an exterior of the electronic device and configured to receive an input from a user;
a button cable electrically connected to the button and configured to transmit an input signal of the button; and
a waterproof bracket having a first surface positioned in an area exposed to moisture introduced from the exterior of the electronic device and a second surface positioned in an area not exposed to moisture,
wherein the waterproof bracket comprises:
a mount configured such that the electrical component is placed therein, and
a cable hole provided through the waterproof bracket from the first surface to the second surface, and
wherein the button cable extends through the cable hole toward a position of the second surface.

2. The electronic device according to claim 1, wherein the waterproof bracket comprises a cable sealing member sealing the cable hole.

3. The electronic device according to claim 1, wherein the waterproof bracket comprises a seal positioned at a boundary between the first surface and the second surface.

4. The electronic device according to claim 1, wherein the mount comprises a recess having an opening on the second surface and configured to accommodate the electrical component.

5. The electronic device according to claim 4, wherein the electrical component comprises a cable extending from the recess to an interior of the electronic device through the opening.

6. The electronic device according to claim 4, wherein the electrical component comprises a directional antenna, and the directional antenna is configured to radiate a signal toward the opening.

7. The electronic device according to claim 4,
wherein at least a portion of an area of the mount in contact with the electrical component is made of a metal material.

8. The electronic device according to claim 7,
wherein the electronic device comprises a first thermal interface positioned on a surface of the mount in contact with the electrical component.

9. The electronic device according to claim 1,
wherein the electronic device comprises a frame made of a metal material,
wherein at least a portion of an area of the waterproof bracket facing the frame is made of a metal material.

10. The electronic device according to claim 9,
wherein the waterproof bracket comprises a second thermal interface positioned between the waterproof bracket and the frame in the area of the waterproof bracket facing the frame.

11. The electronic device according to claim 10,
wherein the second thermal interface comprises a thermally conductive adhesive tape.

12. A waterproof bracket for an electronic device that comprises at least one electrical component positioned therein, a button, and a button cable and provides a waterproof function, the waterproof bracket comprising:
a first surface positioned in an area exposed to moisture introduced from an exterior of the electronic device;
a second surface positioned in an area not exposed to moisture;
a mount configured such that the electrical component is placed therein; and
a cable hole provided through the waterproof bracket from the first surface to the second surface,
wherein the cable hole is configured to allow the button cable to pass from the first surface to the second surface.

13. The waterproof bracket according to claim 12, wherein the waterproof bracket comprises a cable sealing member configured to seal the cable hole.

14. The waterproof bracket according to claim 12, wherein the waterproof bracket comprises a seal positioned at a boundary between the first surface and the second surface.

15. The waterproof bracket according to claim 12, wherein the mount comprises a recess having an opening on the second surface and configured to accommodate the at least one electrical component.

16. The waterproof bracket according to claim 15, wherein the at least one electrical component comprises a cable extending from the recess to an interior of the electronic device through the opening.

17. The waterproof bracket according to claim 15,
wherein the at least one electrical component comprises a directional antenna, and
wherein the opening is configured to provide a radiation path in a direction in which the directional antenna radiates a signal.

18. The waterproof bracket according to claim 12, wherein at least a portion of an area of the mount in contact with the at least one electrical component is made of a metal material.

19. The waterproof bracket according to claim 18, wherein the waterproof bracket comprises a first thermal interface positioned on a surface of the mount in contact with the at least one electrical component.

20. The waterproof bracket according to claim 12,
wherein the electronic device comprises a frame made of a metal material,
wherein at least a portion of an area of the waterproof bracket facing the frame is made of a metal material, and
wherein the waterproof bracket comprises a second thermal interface positioned on a surface of the waterproof bracket facing the frame.
